(19) United States
(12) Patent Application Publication
(10) Pub. No.: US 2017/0193886 A1
(43) Pub. Date: Jul. 6, 2017

(54) Electro-static Discharge Protection Unit, Array Substrate, Display Panel and Display Device

(71) Applicant: BOE Technology Group Co., Ltd., Beijing (CN)

(72) Inventors: Cuili Gai, Beijing (CN); Quanhu Li, Beijing (CN)

(21) Appl. No.: 15/216,744

(22) Filed: Jul. 22, 2016

(30) Foreign Application Priority Data
Jan. 5, 2016 (CN) 201610006935.X

(51) Int. Cl. G09G 3/20; H01L 27/02

(52) U.S. Cl. CPC G09G 3/2092; H01L 27/027; G09G 2330/04

(57) ABSTRACT

Disclosed is an electro-static discharge (ESD) protection unit, an array substrate, a display panel and a display device. The electro-static discharge protection unit comprises n stages of thin film transistors connected in series, wherein n≧2, a control electrode of each stage of thin film transistor is floating, a source electrode of a first stage of thin film transistor is connected with an electro-static generation terminal, a drain electrode of each of the first to ⁿ⁻¹th stages of thin film transistors is connected with a source electrode of a next stage of thin film transistor, respectively, and a drain electrode of a ⁿth stage of thin film transistor is connected with an electro-static discharge terminal; or wherein n≧3, a control electrode of each stage of thin film transistor is floating, a source electrode of a first stage of thin film transistor is connected with a first electro-static generation terminal, a drain electrode of each of the first to ⁿ⁻¹th stages of thin film transistors is connected with a source electrode of a next stage of thin film transistor, respectively, and a drain electrode of a ⁿth stage of thin film transistor is connected with a second electro-static generation terminal. The ESD protection unit can still protect signals in an electro-static generation terminal from being interfered when the thin film transistor adjacent to the electro-static generation terminal is broken down due to ESD, thereby avoiding failure due to ESD.

### CROSS-REFERENCE TO RELATED APPLICATION

This application claims the benefit of Chinese Patent Application No. CN201610006935.X filed on Jan. 5, 2016 in the State Intellectual Property Office of China, the whole disclosure of which is incorporated herein by reference.

### BACKGROUND OF THE INVENTION

Field of the Invention

Embodiments of the present invention relate to field of display technique, in particular to an ESD protection unit, an array substrate, a display panel and a display device.

Description of the Related Art

During manufacturing a tablet display device, chargers would be accumulated. These chargers will cause an electro-static breakdown during being discharged, i.e., Electro-Static Discharge (ESD) , which may result in abnormity of a pixel circuit on an array substrate so that the array substrate cannot operate correctly. Therefore, there is needed to form an ESD protection unit on the array substrate for discharging electro-static chargers in time, thereby preventing the array substrate to be electro-statically damaged.

### SUMMARY OF THE INVENTION

The present invention is intended to solve at least one of the above issues and defects existing in the prior art and provides an ESD protection unit, an array substrate, a display panel and a display device which can still provide protection when a thin film transistor adjacent to an electro-static generation terminal is broken down due to ESD, thereby avoiding failure due to ESD.

According to a first aspect of embodiments of the present invention, there is provided an ESD protection unit comprising n stages of thin film transistors connected in series, where n is an integer larger than or equal to two, wherein a control electrode of each stage of thin film transistor is floating, a source electrode of the first stage of thin film transistor is connected with an electro-static generation terminal, a drain electrode of each of the first to ⁿ⁻¹th stages of thin film transistors is connected with a source electrode of a next stage of thin film transistor, respectively, and a drain electrode of the ⁿth stage of thin film transistor is connected with an electro-static discharge terminal.

According to an exemplary embodiment of the present invention, n=2.

According to an exemplary embodiment of the present invention, the electro-static generation terminal includes a data line or a gate line.

According to an exemplary embodiment of the present invention, the electro-static discharge terminal is a common electrode.

The ESD protection unit according to the first aspect of the present invention comprises at least two stages of thin film transistors. When the first stage of thin film transistor is broken down due to ESD, there are unbroken thin film transistors between the electro-static generation terminal and the electro-static discharge terminal, so that the ESD protection unit can still provide protection without failure, thereby keeping the electro-static generation terminal to be disconnected with the electro-static discharge terminal, so that the electro-static discharge terminal does not interfere with signals in the electro-static generation terminal, thereby avoiding failure due to ESD.

According to a second aspect of the present invention, there is provided an ESD protection unit comprising n stages of thin film transistors connected in series, where n is an integer larger than or equal to three, wherein a control electrode of each stage of thin film transistor is floating, a source electrode of a first stage of thin film transistor is connected with a first electro-static generation terminal, a drain electrode of each of the first to ⁿ⁻¹th stages of thin film transistors is connected with a source electrode of the next stage of thin film transistor, respectively, and a drain electrode of a ⁿth stage of thin film transistor is connected with a second electro-static generation terminal.

According to an exemplary embodiment of the present invention, n=3.

According to an exemplary embodiment of the present invention, each of the first electro-static generation terminal and the second electro-static generation terminal comprises a data line or a gate line.

The ESD protection unit according to the second aspect of the present invention comprises at least three stages of thin film transistors. When the first stage of thin film transistor and the n stage of thin film transistor are simultaneously broken down due to ESD generated in the first electro-static generation terminal and the second electro-static generation terminal, there are still unbroken thin film transistors between the first electro-static generation terminal and the second electro-static generation terminal, so that the ESD protection unit can still provide protection without failure, thereby keeping the first electro-static generation terminal to be disconnected with the second electro-static generation terminal, so that signals in the second electro-static generation terminal and the first electro-static generation terminal will not interfere with each other, thereby avoiding failure due to ESD.

According to a three aspect of the present invention, there is provided an array substrate comprising the ESD protection unit as described above.

The array substrate according to the three aspect of the present invention employs the ESD protection unit as described above. With the array substrate, the signals in the electro-static generation terminal is protected from being interfered when a thin film transistor adjacent to the electro-static generation terminal is broken due to ESD, thereby avoiding failure due to ESD.

According to a fourth aspect of the present invention, there is provided a display panel comprising the array substrate as described above.

The display panel according to the fourth aspect of the present invention employs the array substrate as described above. With the display panel, the signals in the electro-static generation terminal can be protected from being interfered when a thin film transistor adjacent to the electro-static generation terminal is broken due to ESD, thereby avoiding failure due to ESD.

According to a fifth aspect of the present invention, there is provided a display device comprising the display panel as described above.

The display device according to the fifth aspect of the present invention employs the display panel as described above. With the display device, the signals in the electro-static generation terminal can be protected from being interfered when a thin film transistor adjacent to the electro-static generation terminal is broken due to ESD, thereby avoiding failure due to ESD.

### BRIEF DESCRIPTION OF THE DRAWINGS

The accompanying drawings herein can provide further understanding to embodiments of the present invention and form a part of the embodiments of the present invention.

Illustrative embodiments of the present embodiments and their description are intended to explain the present embodiments, rather than being construed as being limited thereto, in which:

FIG. 1 is a schematic view of an ESD protection unit according to an exemplary embodiment of the present invention;

FIG. 2 is a schematic view of an ESD protection unit according to an exemplary embodiment of the present invention shown in FIG. 1; and

FIG. 3 is a schematic view of an ESD protection unit according to another exemplary embodiment of the present invention.

### DETAILED DESCRIPTION OF PREFERRED EMBODIMENTS OF THE INVENTION

Embodiments of the present invention will be described hereinafter in detail with reference the accompanying drawings. It should be noted that the embodiments described herein are intended to only explain and illustrate the present embodiments, rather than being construed as being limited thereto.

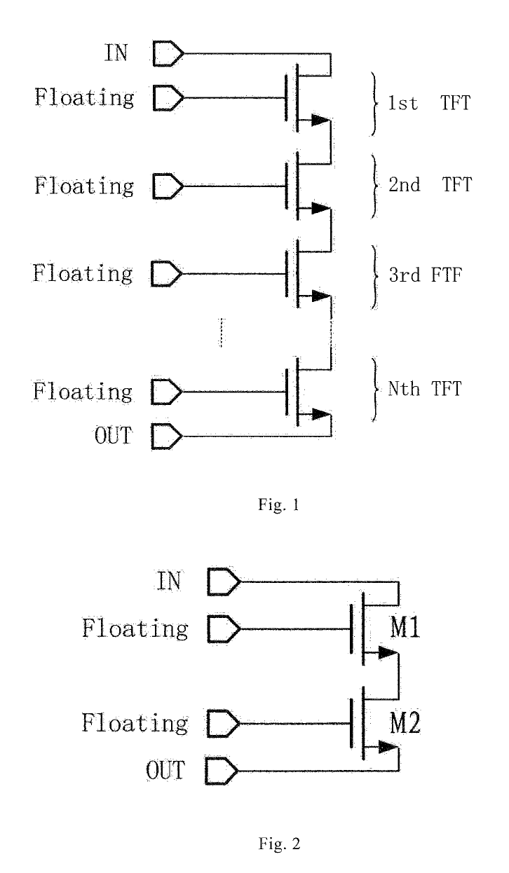

FIG. 1 is a schematic view of an ESD protection unit according to an exemplary embodiment of the present invention. In this embodiment, as shown in FIG. 1, the ESD protection unit comprises n stages of thin film transistors connected in series, wherein n≧2. A control electrode of each stage of thin film transistor is floating. A source electrode of a first stage of thin film transistor is connected with an electro-static generation terminal IN, a drain electrode of each of the first to ⁿ⁻¹th stages of thin film transistors is connected with a source electrode of the next stage of thin film transistor, respectively, and a drain electrode of a ⁿth stage of thin film transistor is connected with an electro-static discharge terminal OUT.

In such an embodiment, when charges in the electro-static generation terminal IN are discharged, i.e., when ESD occurs, the charges transit toward the electro-static discharge terminal OUT. If the charges are relatively larger, the first stage of thin film transistor will be broken down, which causes the source electrode and the drain electrode of the first stage of thin film transistor are shorted, or a gate electrode and the drain electrode thereof are shorted. During this, the charges are discharged. Generally, the ESD is not sufficient to break through a second stage of thin film transistor after breaking down the first stage of thin film transistor. Therefore, taking that the source electrode and the drain electrode of the first stage of thin film transistor are shorted due to ESD as an example, in this case, there are still unbroken second to ⁿth stages of thin film transistors between the electro-static generation terminal IN and the electro-static discharge terminal OUT for preventing electrical connection therebetween. In this way, in a case where the first stage of thin film transistor is broken down, the ESD protection unit can still ensure that the electro-static discharge terminal OUT does not interfere with signals in the electro-static generation terminal IN, thereby avoiding failure due to ESD.

Specifically, the electro-static generation terminal IN comprises a signal line such as a data line, a gate line or the like, and the electro-static discharge terminal OUT comprises a common electrode. In practice, the ESD protection unit will discharge the electro-static charges in the data line or the gate line, thereby ensure signals in the data line or the gate line are stable.

The ESD protection unit according the above embodiment of the present invention comprises at least two stages of thin film transistors. When the first stage of thin film transistor is broken down due to ESD, there are unbroken thin film transistors between the electro-static generation terminal IN and the electro-static discharge terminal OUT, so that the ESD protection unit can still provide protection without failure, thereby preventing the electro-static generation terminal IN and the electro-static discharge terminal OUT from being connected with each other, so that the electro-static discharge terminal OUT does not interfere with the signals in the electro-static generation terminal IN, thereby avoiding failure due to ESD.

FIG. 2 is a schematic view of an ESD protection unit according to a specific embodiment of the ESD protection unit shown in FIG. 1. In this embodiment, an ESD protection unit comprises two stages of thin film transistors. Specifically, as shown in FIG. 2, the ESD protection unit comprises a first thin film transistor M1 and a second thin film transistor M2. Control electrodes, i.e., gate electrodes, of the first thin film transistor M1 and the second thin film transistor M2 are floating. A source electrode of the first thin film transistor M1 is connected with an electro-static generation terminal IN, and a drain electrode of the first thin film transistor M1 is connected with a source electrode of the second thin film transistor M2. A drain electrode of the second thin film transistor M2 is connected with an electro-static discharge terminal OUT. In practice, since a typical ESD would not break through two stages of thin film transistors consecutively, this arrangement thus can further simplify the structure of the ESD protection unit while providing ESD protection, thus reducing cost.

The ESD protection unit illustrated in FIG. 2 has the minimal number of thin film transistors. Even if in this case, generally, when the first thin film transistor M1 is broken down, for example, in the case where the source electrode and the drain electrode thereof are shorted with each other, the second thin film transistor M2 can still prevent the electro-static generation terminal IN from being connected with the electro-static discharge terminal OUT. Therefore, the ESD protection unit can still provide protection without failure. Further, when n>2, there may be more thin film transistors for connecting the electro-static generation terminal IN and the electro-static discharge terminal OUT therebetween. Therefore, even if the ESD breaks through two or more stages (maximally ⁿ⁻¹ stage) of thin film transistors, it is still possible to prevent the electro-static generation terminal IN and the electro-static discharge terminal OUT from being connected with each other and the ESD protection unit will not failed.

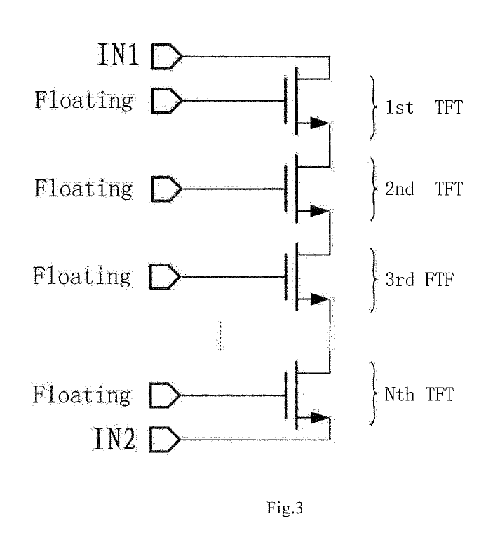

FIG. 3 is a schematic view of an ESD protection unit according to another exemplary embodiment of the present invention. In this embodiment, as shown in FIG. 3, the ESD protection unit comprises n stages of thin film transistors connected in series, wherein n≧3. A control electrode of each stage of thin film transistor is floating. A source electrode of a first stage of thin film transistor is connected with a first electro-static generation terminal IN1, a drain electrode of each of the first to ⁿ⁻¹th stages of thin film transistors is connected with a source electrode of the next stage of thin film transistor, respectively, and a drain electrode of a ⁿth stage of thin film transistor is connected with a second electro-static generation terminal IN2. Specifically, the first electro-static generation terminal IN1 and the second electro-static generation terminal IN2 each comprise a signal line such as a data line, a gate line or the like.

In such an embodiment, when charges in the first electro-static generation terminal IN1 are discharged, i.e., when ESD occurs, the charges transmits toward the second electro-static generation terminal IN2. If the charger is relatively large, it will break down the first stage of thin film transistor, which causes that the source electrode and the drain electrode of the first stage of thin film transistor are shorted, or a gate electrode and the drain electrode thereof are shorted. In this state, the charges are discharged. Similarly, when charges in the second electro-static generation terminal IN2 are discharged, if the charges are relatively large, it will break down a ⁿth stage of thin film transistor, which causes that a source electrode and a drain electrode of the ⁿth stage of thin film transistor are shorted, or a gate electrode and a drain electrode thereof are shorted. In this state, the charges are discharged. Generally, after breaking down one stage of thin film transistor, the ESD is not sufficient to break through the next stage of thin film transistor. Therefore, taking that the source electrodes and the drain electrodes of the first stage of thin film transistor and the ⁿth stage of thin film transistor are shorted simultaneously due to ESD as an example, in this case, there are unbroken second to ⁿ⁻¹th stages of thin film transistors for preventing the first electro-static generation terminal IN1 and the second electro-static generation terminal IN2 from being connected with each other. When n is 3, there is one stage of unbroken thin film transistor, i.e., the second stage of thin film transistor, between the first electro-static generation terminal IN1 and the second electro-static generation terminal IN2. In this way, in a case where the first stage of thin film transistor and the ⁿth stage of thin film transistor are broken down, the ESD protection unit can still provide protection without failure and ensure that signals in the first electro-static generation terminal IN1 and the second electro-static generation terminal IN2 will not interfere with each other, thereby avoiding failure due to ESD. When n is greater than 3, there are more stages of unbroken thin film transistors between the first electro-static generation terminal IN1 and the second electro-static generation terminal IN2. Therefore, even if two or more stages (maximally ⁿ⁻¹ stage) of thin film transistors are broken down due to ESD occurring at the first electro-static generation terminal IN1 and the second electro-static generation terminal IN2, it is possible to prevent the first electro-static generation terminal IN1 and the second electro-static generation terminal IN2 from being connected with each other, so that the ESD protection unit can provide protection without failure.

The ESD protection unit according another embodiment of the present invention comprises at least three stages of thin film transistors. When the first stage of thin film transistor and the n stage of thin film transistor are simultaneously broken down due to ESD occurring at both the first electro-static generation terminal IN1 and the second electro-static generation terminal IN2 simultaneously, there are unbroken thin film transistors between the first electro-static generation terminal IN1 and the second electro-static generation terminal IN2, so that the ESD protection unit can still provide protection without failure, thereby preventing the first electro-static generation terminal IN1 and the second electro-static generation terminal IN2 from being connected with each other, so that signals in the second electro-static generation terminal IN2 and the first electro-static generation terminal IN1 will not interfere with each other, thereby avoiding failure due to ESD.

In an exemplary embodiment of the present invention, n=3, i.e., the ESD protection unit comprises three stages of thin film transistors. In practice, since the typical ESD would not break through two stages of thin film transistors consecutively, this arrangement thus can simplify the structure of the ESD protection unit while providing ESD protection, thus reducing cost.

According to another exemplary embodiment of the present invention, there is also provided an array substrate comprising the ESD protection unit as described in any one of the above embodiments.

The array substrate according to embodiments of the present invention employs the ESD protection unit as described in any one of the above embodiments. Therefore, with the array substrate, signals in the electro-static generation terminal can be prevented from being interfered when a thin film transistor adjacent to the electro-static generation terminal is broken down due to ESD, thereby avoiding failure due to ESD.

According to yet another embodiment of the present invention, there is further provided a display panel comprising the array substrate as described above.

The display panel according to embodiments of the present invention employs the array substrate as described above. Therefore, with the display panel, signals in the electro-static generation terminal can be prevented from being interfered when a thin film transistor adjacent to the electro-static generation terminal is broken down due to ESD, thereby avoiding failure due to ESD.

According to still another embodiment of the present invention, there is further provided a display device comprising the display panel as described above.

The display device according to embodiments of the present invention employs the display panel as described above. Therefore, with the display device, signals in the electro-static generation terminal can be protected from being interfered when a thin film transistor adjacent to the electro-static generation terminal is broken down due to ESD, thereby avoiding failure due to ESD.

It should be understood that the above embodiments are merely exemplary embodiments for illustrating the principle of the present invention, and the present invention is not limited thereto. It would be appreciated by those skilled in the art that various changes or modifications may be made to the embodiments of the present disclosure without departing from the principle and spirit thereof, and these changes or modifications should be fall within the scope of the present invention.

What is claimed is:

1. An electro-static discharge protection unit comprising n stages of thin film transistors connected in series, where n is an integer larger than or equal to two, wherein
a control electrode of each stage of thin film transistor is floating, a source electrode of the first stage of thin film transistor is connected with an electro-static generation terminal, a drain electrode of each of the first to ⁿ⁻¹th stages of thin film transistors is connected with a source electrode of a next stage of thin film transistor, respectively, and a drain electrode of the ⁿth stage of thin film transistor is connected with an electro-static discharge terminal.

2. The electro-static discharge protection unit according to claim 1, wherein n is equal to two.

3. The electro-static discharge protection unit according to claim 1, wherein the electro-static generation terminal comprises a data line or a gate line.

4. The electro-static discharge protection unit according to claim 1, wherein the electro-static discharge terminal comprises a common electrode.

5. An electro-static discharge protection unit comprising n stages of thin film transistors connected in series, where n is an integer larger than or equal to three, wherein
a control electrode of each stage of thin film transistor is floating, a source electrode of the first stage of thin film transistor is connected with a first electro-static generation terminal, a drain electrode of each of the first to ⁿ⁻¹th stages of thin film transistors is connected with a source electrode of a next stage of thin film transistor, respectively, and a drain electrode of the ⁿth stage of thin film transistor is connected with a second electro-static generation terminal.

6. The electro-static discharge protection unit according to claim 5, wherein n is equal to three.

7. The electro-static discharge protection unit according to claim 5, wherein each of the first electro-static generation terminal and the second electro-static generation terminal comprises a data line or a gate line.

8. An array substrate, comprising the electro-static discharge protection unit according to claim 1.

9. The array substrate according to claim 8, wherein the n is equal to two.

10. The array substrate according to claim 8, wherein the electro-static generation terminal comprises a data line or a gate line.

11. The array substrate according to claim 8, wherein the electro-static discharge terminal comprises a common electrode.

12. An array substrate, comprising the electro-static discharge protection unit according to claim 5.

13. The array substrate according to claim 12, wherein n is equal to three.

14. The array substrate according to claim 12, wherein each of the first electro-static generation terminal and the second electro-static generation terminal comprises a data line or a gate line.

15. A display panel, comprising the array substrate according to claim 8.

16. The display panel according to claim 15, wherein the electro-static generation terminal includes a data line or a gate line, and the electro-static discharge terminal comprises a common electrode.

17. A display panel, comprising the array substrate according to claim 12.

18. The display panel according to claim 17, wherein each of the first electro-static generation terminal and the second electro-static generation terminal comprises a data line or a gate line.

19. A display device, comprising the display panel according to claim 15.

20. A display device, comprising the display panel according to claim 17.
